(19) United States
(12) Patent Application Publication
(10) Pub. No.: US 2022/0068615 A1
(43) Pub. Date: Mar. 3, 2022

(54) STAGE AND PLASMA PROCESSING APPARATUS

(71) Applicant: Tokyo Electron Limited, Tokyo (JP)

(72) Inventor: Shinsuke OKA, Miyagi (JP)

(21) Appl. No.: 17/462,787

(22) Filed: Aug. 31, 2021

(30) Foreign Application Priority Data
Sep. 2, 2020 (JP) 2020-147793

(51) Int. Cl. H01J 37/32

(52) U.S. Cl. CPC H01J 37/32642; H01J 37/32568; H01J 37/32724

(57) ABSTRACT

A stage includes a first placement table on which a substrate is placed, and a second placement table configured to place thereon a ring-shaped edge ring arranged around the substrate. The second placement table includes an electrostatic clamping electrode configured to clamp the edge ring by being applied with a voltage, and a temperature adjuster provided on at least one of an inner peripheral side and an outer peripheral side of the edge ring with respect to the electrostatic clamping electrode.

### CROSS-REFERENCE TO RELATED APPLICATION

This application is based upon and claims the benefit of priority from Japanese Patent Application No. 2020-147793, filed on Sep. 2, 2020, the entire contents of which are incorporated herein by reference.

### TECHNICAL FIELD

The present disclosure relates to a stage and a plasma processing apparatus.

### BACKGROUND

Patent Document 1 discloses a stage having a configuration in which a deposit control ring is arranged radially inside a focus ring with a gap interposed therebetween.

### PRIOR ART DOCUMENT

### Patent Document

[Patent Document 1: Japanese Laid-Open Patent Publication No. 2019-220497

### SUMMARY

According to embodiments of the present disclosure, there is provided a stage including a first placement table on which a substrate is placed, and a second placement table configured to place thereon a ring-shaped edge ring arranged around the substrate, wherein the second placement table includes an electrostatic clamping electrode configured to clamp the edge ring by being applied with a voltage, and a temperature adjuster provided on at least one of an inner peripheral side and an outer peripheral side of the edge ring with respect to the electrostatic clamping electrode.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view schematically illustrating an outline a configuration of a plasma processing apparatus according to a first embodiment.

FIG. 2 is an enlarged view of a main part illustrating an outline of a configuration of a stage according to the first embodiment.

FIG. 3A is a view illustrating an example of arrangement regions of a first electrostatic clamping electrode, a second electrostatic clamping electrode, and heaters according to the first embodiment.

FIG. 3B is a view illustrating another example of the second electrostatic clamping electrode according to the first embodiment.

FIG. 3C is a view illustrating another example of the second electrostatic clamping electrode according to the first embodiment.

FIG. 4 is a schematic cross-sectional view illustrating a configuration of a main part of a conventional stage.

FIG. 5 is a view illustrating another example of arrangement regions of the first electrostatic clamping electrode, the second electrostatic clamping electrode, and heaters according to the first embodiment.

FIG. 6 is a schematic cross-sectional view illustrating a configuration of a main part of a stage according to a second embodiment.

FIG. 7 is a schematic cross-sectional view illustrating a configuration of a main part of a stage according to a third embodiment.

FIG. 8 is a view illustrating an example of arrangement regions of a first electrostatic clamping electrode, a second electrostatic clamping electrode, and a Peltier element according to the third embodiment.

FIG. 9 is a schematic cross-sectional view illustrating a configuration of a main part of a stage according to a fourth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a stage and a plasma processing apparatus disclosed herein will be described in detail with reference to the drawings. The stage and the plasma processing apparatus disclosed herein are not limited by the embodiments.

In a semiconductor device manufacturing process, plasma processing such as plasma etching is performed on a substrate such as a semiconductor wafer using a plasma processing apparatus. The plasma processing apparatus generates plasma by exciting a processing gas in a chamber depressurized to a predetermined degree of vacuum, and performs plasma processing on a substrate using the plasma. The plasma processing apparatus includes, in the chamber, a stage on which a substrate is placed. In addition, in the plasma processing apparatus, a ring-shaped edge ring (also called a focus ring) is placed around the substrate on the stage in order to maintain the substrate in in-plane uniformity of plasma processing and to protect the outer peripheral portion of the stage. In the plasma processing apparatus, the substrate and the edge ring are electrostatically clamped to the stage.

In the plasma processing apparatus, the temperature of the edge ring rises due to heat input from the plasma during the plasma processing, so that a gap between the edge ring and the placement surface on which the edge ring is placed is widened. A by-product produced by plasma processing is deposited in the widened gap. The deposited by-product is called a deposit. In the plasma processing apparatus, as the cumulative number of plasma-processed substrates increases, the deposit accumulates in the gap, and the thickness of the deposit increases. When the plasma processing is completed, the gap between the edge ring and the placement surface returns to the original width, but when the thickness of the deposit exceeds the width of the gap, stress is generated upwards with respect to the edge ring. When the thickness of the deposit further increases, problems will occur.

Therefore, a technique for suppressing the deposition of a by-product in the gap between the edge ring and the placement surface on which the edge ring is placed is needed.

### First Embodiment

### <Plasma Processing Apparatus>

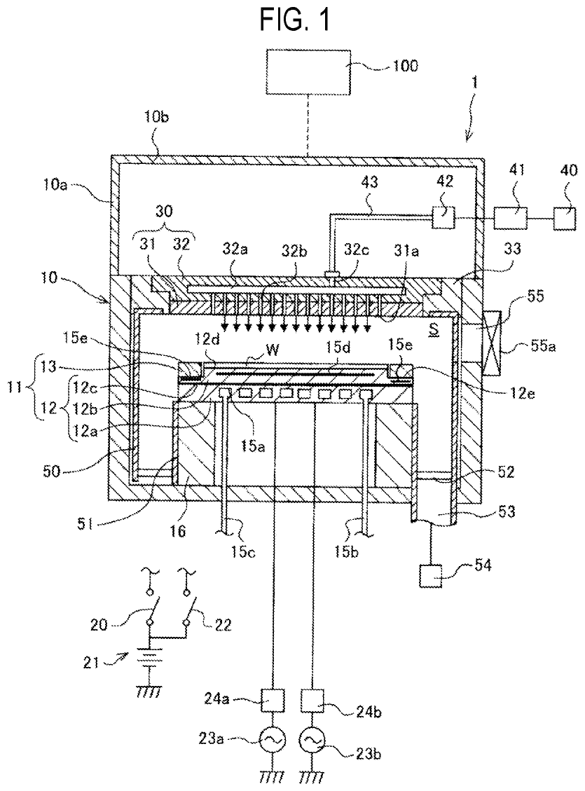

An embodiment will be described. First, a schematic configuration of a plasma processing apparatus 1 according to a first embodiment will be described. FIG. 1 is a vertical cross-sectional view schematically illustrating an outline of the configuration of the plasma processing apparatus 1 according to the first embodiment. In this embodiment, a capacitively coupled parallel plate plasma etching apparatus is described as an example of the plasma processing apparatus 1.

As illustrated in FIG. 1, the plasma processing apparatus 1 includes a substantially cylindrical chamber 10. The chamber 10 is made of, for example, aluminum. The surface of the chamber 10 is anodized. The chamber 10 defines a processing space S in which plasma is generated.

Within the chamber 10, a stage 11, on which a substrate W as a target of plasma processing, such as a semiconductor wafer, is placed, is provided. The stage 11 includes a base 12 and an edge ring 13. The edge ring 13 is formed in a ring shape and is arranged on the stage 11 to surround the periphery of the substrate W.

The base 12 includes a base part 12a, a first placement table 12b, and a second placement table 12c. The first placement table 12b and the second placement table 12c are provided on the base part 12a. On the top surface of the first placement table 12b, a placement surface 12d on which the substrate W is placed is formed. The first placement table 12b holds the substrate W placed on the placement surface 12d. On the top surface of the second placement table 12c, a placement surface 12e on which the edge ring 13 is placed is formed. The second placement table 12c holds the edge ring 13 placed on the placement surface 12e.

The base part 12a has a substantially disk-like shape and has a diameter larger than the diameter of the substrate W. The diameter of the substrate W is about 300 mm. The first placement table 12b has a substantially disk-like shape having a diameter similar to the diameter of the base part 12a or smaller than the diameter of the base part 12a, and is provided coaxially with the base part 12a. The second placement table 12c has a substantially annular shape, and is provided on the radial outer side of the base part 12a to surround the periphery of the first placement table 12b in a plan view. The edge ring 13 is formed to be thicker than the substrate W. The first placement table 12b is formed to be higher than the second placement table 12c such that the heights of the top surface of the placed substrate W and the top surface of the edge ring 13 are aligned to each other. The top surface of the first placement table 12b is located above the top surface of the second placement table 12c in a side view. The first placement table 12b and the second placement table 12c may be integrally formed of the same member, or may be formed as separate bodies and combined to be integrated with each other.

A coolant flow path 15a is formed inside the base part 12a. A coolant is supplied to the coolant flow path 15a from a chiller unit (not illustrated) provided outside the chamber 10 via a coolant inlet pipe 15b. The coolant supplied to the coolant flow path 15a returns to the chiller unit via a coolant outlet pipe 15c. The substrate W placed on the first placement table 12b, the edge ring 13 held on the second placement table 12c, and the stage 11 itself may be cooled to a predetermined temperature of, for example, 30 degrees C. to 50 degrees C. by circulating the coolant, such as cooling water, in the coolant flow path 15a. The base part 12a is made of a conductive metal, such as aluminum, and functions as a lower electrode.

The first placement table 12b is made of, for example, ceramic, and is provided with a first electrostatic clamping electrode 15d therein. A DC power supply 21 is connected to the first electrostatic clamping electrode 15d via a switch 20. Then, the first placement table 12b clamps the substrate W on the placement surface 12d by an electrostatic force generated by applying a DC voltage from the DC power supply 21 to the first electrostatic clamping electrode 15d. That is, the first placement table 12b functions as an electrostatic chuck for the substrate W.

The second placement table 12c is made of, for example, ceramic, and is provided with a second electrostatic clamping electrode 15e therein. The DC power supply 21 is connected to the second electrostatic clamping electrode 15e via a switch 22. Then, the second placement table 12c clamps the edge ring 13 on the placement surface 12e by an electrostatic force generated by applying the DC voltage from the DC power supply 21 to the second electrostatic clamping electrode 15e. That is, the second placement table 12c functions as an electrostatic chuck for the edge ring 13.

The DC power supply for applying the DC voltage to the second electrostatic clamping electrode 15e may be provided separately from the DC power supply 21 for applying the DC voltage to the first electrostatic clamping electrode 15d.

On the placement surface 12e of the second placement table 12c, the edge ring 13 formed in an annular shape is clamped by the second electrostatic clamping electrode 15e. The edge ring 13 surrounds the substrate W placed on the first placement table 12b in a plan view, and is held coaxially with the first placement table 12b. The edge ring 13 is provided in order to improve the uniformity of plasma processing. Therefore, the edge ring 13 is made of the same material as the substrate W placed on the first placement table 12b, for example, silicon (Si) constituting the substrate W in this embodiment.

As described above, the edge ring 13 is clamped by the second placement table 12c by an electrostatic force. At this time, the edge ring 13 is cooled by the coolant flowing through the coolant flow path 15a formed inside the base part 12a via the second placement table 12c. In this way, the edge ring 13 is configured to be cooled by being clamped to the second placement table 12c.

A first radio frequency (RF) power supply 23a is connected to the base part 12a of the base 12 via a first matcher 24a. In addition, a second RF power supply 23b is connected to the base part 12a via a second matcher 24b. When implementing plasma processing, high-frequency power is supplied to the stage 11 from each of the first RF power supply 23a and the second RF power supply 23b.

The first RF power supply 23a is a power supply that generates high-frequency power for plasma generation. The frequency from the first RF power supply 23a may be 27 MHz to 100 MHz, and in an example, high-frequency power of 40 MHz is supplied to the base part 12a of the stage 11. The first matcher 24a includes a circuit for matching the output impedance of the first RF power supply 23a with the input impedance on the load side (the base part 12a side).

The second RF power supply 23b generates high-frequency power for drawing ions into the substrate W (high-frequency bias power), and supplies the high-frequency bias power to the base part 12a. The frequency of the high-frequency bias power may be in the range of 400 kHz to 13.56 MHz, and in an example, the frequency is 3 MHz. The second matcher 24b includes a circuit for matching the output impedance of the second RF power supply 23b with the input impedance on the load side (the base part 12a side).

The stage 11 configured as described above is fastened to a substantially cylindrical support member 16 provided on the bottom of the chamber 10. The support member 16 is made of an insulator such as ceramic.

A shower head 30 is provided above the stage 11 to face the stage 11. The shower head 30 functions as an upper electrode. The shower head 30 includes an electrode plate 31 arranged to face the processing space S and an electrode support 32 provided above the electrode plate 31. The electrode plate 31 functions as a pair of electrodes (an upper electrode and a lower electrode) with the base part 12a. In addition, the shower head 30 is supported in the upper portion of the chamber 10 via an insulating blocking member 33.

The electrode plate 31 includes a plurality of gas jet holes 31a formed therein to supply a processing gas sent from a gas diffusion chamber 32a (described later) to the processing space S. The electrode plate 31 is made of, for example, a conductor or a semiconductor having a low electrical resistivity generating little Joule heat.

The electrode support 32 detachably supports the electrode plate 31. The electrode support 32 is made of a conductive material such as aluminum having an anodized surface. A gas diffusion chamber 32a is formed inside the electrode support 32. In the gas diffusion chamber 32a, a plurality of gas flow holes 32b communicating with the gas jet holes 31a are formed. In addition, a gas source group 40 configured to supply a processing gas to the gas diffusion chamber 32a is connected to the electrode support 32 through a flow rate controller group 41, a valve group 42, a gas supply pipe 43, and a gas introduction hole 32c.

The gas source group 40 includes gas sources of various gases used for plasma processing. The gas source group 40 supplies one or more types of gases from the gas source as processing gases to the gas diffusion chamber 32a via the flow rate controller group 41, the valve group 42, the gas supply pipe 43, and the gas introduction hole 32c. The processing gases supplied to the gas diffusion chamber 32a are dispersed and supplied in the form of a shower in the processing space S via the gas flow holes 32b and the gas jet holes 31a.

Further, the plasma processing apparatus 1 is provided with a cylindrical ground conductor 10a to extend above the height position of the shower head 30 from the side wall of the chamber 10. The cylindrical ground conductor 10a has a ceiling plate 10b in the upper portion thereof.

In the plasma processing apparatus 1, a deposition shield 50 is detachably provided along the inner wall of the chamber 10. The deposition shield 50 suppresses adhesion of a deposit to the inner wall of the chamber 10. The deposition shield 50 is configured by, for example, coating an aluminum material with ceramic such as Y₂O₃. Similarly, a deposition shield 51 is detachably provided on the outer peripheral surface of the support member 16 facing the deposition shield 50.

In the bottom of the chamber 10, an exhaust plate 52 is provided between the inner wall of the chamber 10 and the support member 16. The exhaust plate 52 is configured by coating, for example, an aluminum material with ceramic such as Y₂O₃. The processing space S communicates with an exhaust port 53 through the exhaust plate 52. An exhauster 54, such as a vacuum pump, is connected to the exhaust port 53. The exhauster 54 depressurizes the interior of the processing space S to a predetermined degree of vacuum.

In addition, a substrate W carry-in/out port 55 is formed in the side wall of the chamber 10. The carry-in/out port 55 can be opened/closed by the gate valve 55a.

The plasma processing apparatus 1 described above is provided with a controller 100. The controller 100 is, for example, a computer, and has a storage part (not illustrated). The storage part stores a program that controls the processing of a substrate W in the plasma processing apparatus 1. The storage part also stores a control program for controlling various kinds of processing by a processor and programs for causing respective components of the plasma processing apparatus 1 to execute processing depending on processing conditions, that is, processing recipes. The programs may be recorded in a non-transitory computer-readable storage medium, and may be installed on the controller 100 from the storage medium.

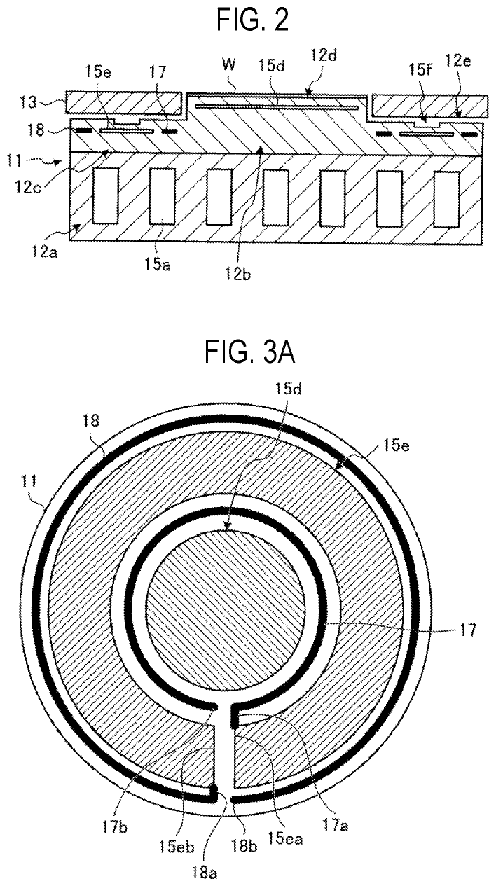

Next, the stage 11 according to the first embodiment will be described with reference to FIG. 2. FIG. 2 is an enlarged view of a main part illustrating an outline of the configuration of the stage 11 according to the first embodiment.

The stage 11 includes a base 12 and an edge ring 13. The base 12 includes a first placement table 12b configured to clamp a substrate W, a second placement table 12c configured to clamp the edge ring 13, and a base part 12a having a top surface on which the first placement table 12b and the second placement table 12c are provided. The base part 12a has a substantially disk-like shape. The first placement table 12b has a substantially disk shape, and is fixed above the base part 12a via, for example, an adhesive to be coaxial with the base part 12a. In addition, the second placement table 12c has a substantially annular shape, and is fixed to the radial outer side of the base part 12a via, for example, an adhesive to surround the first placement table 12b. As described above, the first placement table 12b is provided such that the top surface of the first placement table 12b is located higher than the top surface of the second placement table 12c in a side view. A coolant flow path 15a is formed inside the base part 12a.

A first electrostatic clamping electrode 15d configured to clamp a substrate W is provided inside the first placement table 12b. The first electrostatic clamping electrode 15d is provided to correspond to the placement region on which the substrate W is placed. The first placement table 12b clamps the substrate W on the placement surface 12d by an electrostatic force generated by applying a DC voltage to the first electrostatic clamping electrode 15d.

A second electrostatic clamping electrode 15e configured to clamp the edge ring 13 is provided inside the second placement table 12c. The second placement table 12c clamps the edge ring 13 on the placement surface 12e by an electrostatic force generated by applying a DC voltage to the second electrostatic clamping electrode 15e.

The edge ring 13 has an annular shape having a substantially rectangular cross section, and is provided to surround the substrate W placed on the first placement table 12b.

The second placement table 12c is provided with a recess 15f in the radial center of the annular placement surface 12e on which the edge ring 13 is placed. The recess 15f extends in an annular shape in the circumferential direction of the annular placement surface 12e. A heat transfer gas (e.g., He gas) is supplied to the recess 15f through a pipe (not illustrated) provided in the second placement table 12c.

During the plasma processing, the plasma processing apparatus 1 applies a DC voltage from the DC power supply 21 to the first electrostatic clamping electrode 15d and the second electrostatic clamping electrode 15e under the control of the controller 100 to clamp the substrate W and the edge ring 13. In addition, in the plasma processing apparatus 1, the heat transfer gas is supplied to the recess 15f in order to improve the heat transfer efficiency to the edge ring 13 under the control of the controller 100 during the plasma processing.

In the plasma processing apparatus 1, the temperature of the edge ring 13 rises due to heat input from the plasma during the plasma processing, and the gap between the edge ring 13 and the placement surface 12e on which the edge ring 13 is placed is widened. A deposit (by-product) generated by the plasma processing is deposited in the widened gap. When the thickness of the deposit increases, problems will occur.

Therefore, the stage 11 according to the first embodiment is provided with heaters 17 and 18 in the second placement table 12c. The heater 17 is provided on the inner peripheral side of the edge ring 13 with respect to the second electrostatic clamping electrode 15e. The heater 18 is provided on the outer peripheral side of the edge ring 13 with respect to the second electrostatic clamping electrode 15e.

The second electrostatic clamping electrode 15e is provided along the vicinity of the center of the placement surface 12e with a width smaller than the radial width of the placement surface 12e. The heater 17 and the heater 18 are provided in the same plane as the arrangement surface on which the second electrostatic clamping electrode 15e is arranged such that the regions in which the heaters 17 and 18 are arranged do not overlap the region of the second electrostatic clamping electrode 15e.

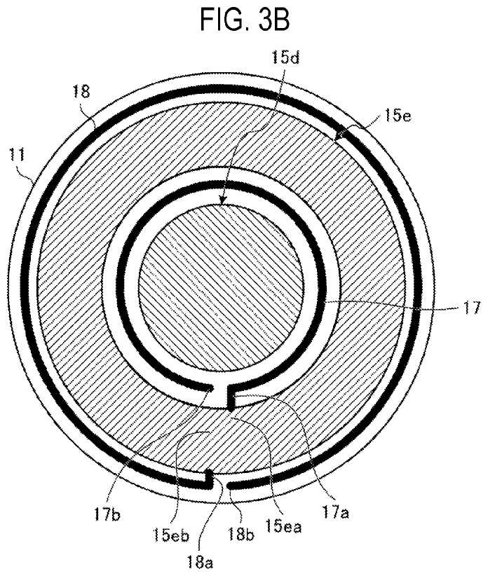

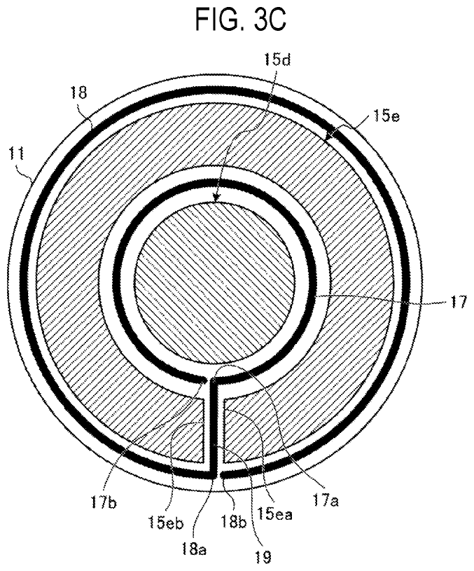

FIG. 3A is a view illustrating an example of arrangement regions of the first electrostatic clamping electrode 15d, the second electrostatic clamping electrode 15e, and the heaters 17 and 18 according to the first embodiment. FIG. 3A illustrates a conceptual view of the stage 11 viewed from above (at the placement surface 12d, 12e side). The stage 11 is formed in a circular shape when viewed from above. A circular arrangement region provided with the first electrostatic clamping electrode 15d is illustrated in the vicinity of the center of the stage 11. In addition, an annular arrangement region, which is provided with the second electrostatic clamping electrode 15e to surround the arrangement region of the first electrostatic clamping electrode 15d, is also illustrated. The arrangement region of the first electrostatic clamping electrode 15d has about the same size as the substrate W. Since the radial width of the second electrostatic clamping electrode 15e is smaller than the radial width of the placement surface 12e, the inner diameter of the arrangement region of the second electrostatic clamping electrode 15e is larger than the inner diameter of the edge ring 13, and the outer diameter of the arrangement region of the second electrostatic clamping electrode 15e is smaller than the outer diameter of the edge ring 13. The heater 17 is provided along the inner periphery of the second electrostatic clamping electrode 15e between the arrangement region of the first electrostatic clamping electrode 15d and the arrangement region of the second electrostatic clamping electrode 15e. The heater 18 is provided along the outer periphery of the arrangement region of the second electrostatic clamping electrode 15e. The second electrostatic clamping electrode 15e, the heater 17, and the heater 18 are formed by screen-printing the same conductive material. The second electrostatic clamping electrode 15e is formed in a wide width in order to lower the resistance and generate an electrostatic force for clamping the edge ring 13. The heater 17 and the heater 18 are formed in a narrow width in order to increase the resistance value to generate heat. A portion of the annular shape of the second electrostatic clamping electrode 15e is removed. One end 17a of the heater 17 is connected to one end 15ea of the second electrostatic clamping electrode 15e. The other end 15eb of the second electrostatic clamping electrode 15e is connected to one end 18a of the heater 18. That is, the heater 17, the second electrostatic clamping electrode 15e, and the heater 18 are electrically connected in series. One of the other end 17b of the heater 17 and the other end 18b of the heater 18 is connected to the DC power supply 21 via the switch 22. The other of the other end 17b of the heater 17 and the other end 18b of the heater 18 is also connected to the DC power supply 21. In this case, as the DC power supply 21, two DC power supplies, i.e., a high-voltage DC power supply and a low-voltage DC power supply, are provided. In this case, it is necessary to generate a potential difference between the other end 17b of the heater 17 and the other end 18b of the heater 18, for example, by connecting the high-voltage DC power supply to the end 17b of the heater 17 to apply a high voltage and connecting the low-voltage DC power supply to the end 18b of the heater 18 to apply a low voltage. The DC power supply 21 applies a DC voltage to the series circuit of the heater 17, the second electrostatic clamping electrode 15e, and the heater 18. The second electrostatic clamping electrode 15e clamps the edge ring 13 by being applied with the DC voltage. The heaters 17 and 18 generate heat when the DC voltage is applied. In addition, the second electrostatic clamping electrode 15e may be formed in an annular shape without removing a portion thereof. FIG. 3B is a view illustrating another example of the second electrostatic clamping electrode according to the first embodiment. In FIG. 3B, the second electrostatic clamping electrode 15e is formed in an annular shape. In addition, the second electrostatic clamping electrode 15e may not be connected to the heaters 17 and 18, and the heaters 17 and 18 may be connected in series. FIG. 3C is a view illustrating another example of the second electrostatic clamping electrode according to the first embodiment. The second electrostatic clamping electrode may be formed in an annular shape without removing a portion thereof. A portion of the annular shape of the second electrostatic clamping electrode 15e is removed. The end 17a of the heater 17 and the end 18a of the heater 18 are connected to each other via a wire 19 provided in the area in which the portion of the second electrostatic clamping electrode 15e is removed. It is preferable to form the wire 19 in a width in which heat generation does not cause a problem. In addition, it is necessary to provide a plurality of DC power supplies. For example, in FIG. 3B, the end 17b of the heater 17 is connected to a DC power supply, the application voltage of which is V2. In addition, the end 18b of the heater 18 is connected to a DC power supply, the application voltage of which is V1. Here, it is assumed that the voltage V1>the voltage V2>>0. As a result, the voltage of V1-V2 is applied to the heaters 17 and 18 for heat generation. Meanwhile, since the second electrostatic clamping electrode 15e is formed in a wide width, the entire surface thereof has substantially the same potential, for example, a voltage of (V2+V1)/2.

In the stage 11 according to the first embodiment, it is possible to raise the temperatures of the inner peripheral side and the outer peripheral side of the edge ring 13 by providing the heaters 17 and 18 on the inner peripheral side and the outer peripheral side of the edge ring 13 and heating the inner peripheral side and the outer peripheral side of the edge ring 13. A by-product produced by plasma processing is unlikely to adhere to hot portions. Therefore, with the stage 11, it is possible to suppress the deposition of a deposit in the gap between the edge ring 13 and the placement surface 12e, on which the edge ring 13 is placed.

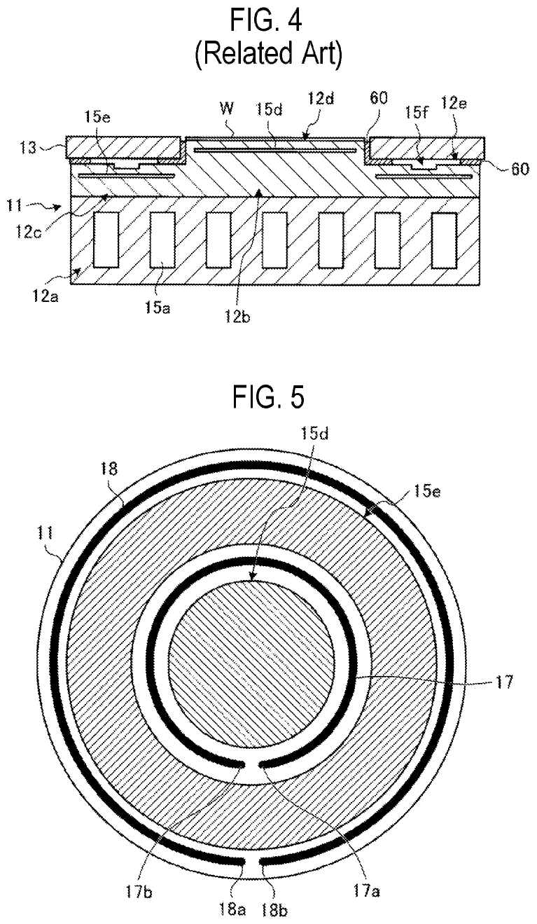

Here, as a comparative example, an example of the configuration of the conventional stage 11 is illustrated. FIG. 4 is a schematic cross-sectional view illustrating the configuration of a main part of the conventional stage 11. The conventional stage 11 is not provided with heaters 17 and 18. In this case, the deposit 60 is deposited in the gap between the edge ring 13 and the placement surface 12e. In the plasma processing apparatus, as the cumulative number of plasma-processed substrates increases, the deposition of the deposit 60 progresses, and the thickness of the deposit 60 increases. When the plasma processing is completed, the gap between the edge ring 13 and the placement surface 12e returns to the original width, but when the thickness of the deposit 60 increases to exceed the width of the gap, stress is applied upwards to the edge ring 13. When the thickness of the deposit 60 further increases, problems will occur. For example, when the thickness of the deposit 60 further increases, the heat transfer gas supplied to the rear surface side of the edge ring 13 leaks, and the plasma processing cannot be performed. In the plasma processing apparatus, when the leakage of the heat transfer gas occurs, the apparatus is stopped, the chamber is opened to the atmosphere, and the deposit is removed. Once the chamber is opened to the atmosphere, it takes several days for the plasma processing apparatus to be ready to process substrates. Thus, the operating rate is reduced.

Meanwhile, the stage 11 according to the first embodiment is heated by providing heaters 17 and 18 on the inner peripheral side and the outer peripheral side of the edge ring 13, as illustrated in FIG. 2. The higher the temperature, the lower the rate of deposition of a by-product. Therefore, with the stage 11 according to the first embodiment, it is possible to suppress the deposition of a deposit in the gap between the edge ring 13 and the placement surface 12e. Therefore, with the stage 11 according to the first embodiment, it is possible to extend the time until the heat transfer gas leaks. As a result, in the stage 11 according to the first embodiment, it is possible to prolong the cycle of opening the chamber 10 to the atmosphere in order to remove the deposit 60, and thus it is possible to suppress a decrease in the operating rate. In the case in which the plasma processing apparatus 1 performs plasma cleaning for the purpose of removing the deposit 60, when a higher temperature causes an increase in the rate of removal of a by-product in view of the chemical reaction between the by-product and the etching gas, the temperature may be raised through heating by the heaters 17 and 18. When a higher temperature causes a decrease in the rate of removal of a by-product, the heating by the heaters 17 and 18 is not performed.

The case in which, in the stage 11 according to the first embodiment, the heaters 17 and 18 are provided on both the inner peripheral side and the outer peripheral side of the edge ring 13 with respect to the second electrostatic clamping electrode 15e has been described as an example, but the stage 11 is not limited thereto. The stage 11 may be provided with only one of the heaters 17 and 18. That is, the stage 11 may have a heater on at least one of the inner peripheral side and the outer peripheral side of the edge ring 13 with respect to the second electrostatic clamping electrode 15e.

In addition, the case in which, in the stage 11, the heater 17, the second electrostatic clamping electrode 15e, and the heater 18 are electrically connected in series has been described as an example, but the stage is not limited thereto. The stage 11 may be configured such that a voltage can be individually applied to the heater 17, the second electrostatic clamping electrode 15e, and the heater 18. FIG. 5 is a view illustrating another example of arrangement regions of the first electrostatic clamping electrode 15d, the second electrostatic clamping electrode 15e, and the heaters 17 and 18 according to the first embodiment.

The second electrostatic clamping electrode 15e is connected to the DC power supply 21 so that a DC voltage is applied thereto from the DC power supply 21. The heaters 17 and 18 may be configured such that the ends 17a and 17b and the ends 18a and 18b are connected to different DC power supplies and are applied with a DC voltages from the DC power supplies, respectively. This makes it possible to individually control the clamping of the edge ring 13 by the second electrostatic clamping electrode 15e and the heating by the heaters 17 and 18.

As described above, the stage 11 according to the first embodiment includes a first placement table 12b configured to place thereon a substrate W and a second placement table 12c configured to place thereon an edge ring 13 arranged around the substrate W. The second placement table 12c includes the second electrostatic clamping electrode 15e and the heaters 17 and 18 (a temperature adjuster). The second electrostatic clamping electrode 15e clamps the edge ring 13 by being applied with the voltage. The heaters 17 and 18 are provided on at least one of the inner peripheral side and the outer peripheral side of the edge ring 13 with respect to the second electrostatic clamping electrode 15e. Therefore, with the stage 11, it is possible to suppress the deposition of a deposit in the gap between the edge ring 13 and the placement surface 12e, on which the edge ring 13 is placed.

The heaters 17 and 18 are placed on the second placement table 12c such that the regions in which the heaters 17 and 18 are arranged do not overlap the region of the second electrostatic clamping electrode 15e when viewed from the placement surface 12e side on which the edge ring 13 is placed. Therefore, with the stage 11, it is possible to suppress the deposition of a deposit in the gap while maintaining the clamping force of the edge ring 13.

The heaters 17 and 18 are provided on the same surface as the arrangement surface on which the second electrostatic clamping electrode 15e is arranged. Therefore, with the stage 11, it is possible to form the heaters 17 and 18 and the second electrostatic clamping electrode 15e at once in the same process through screen-printing or the like.

The heaters 17 and 18 are provided along the entire circumference of the second placement table 12c. Therefore, in the stage 11, it is possible to suppress the deposition of a deposit in the gap between the edge ring 13 and the placement surface 12e along the entire circumference of the second placement table 12c.

### Second Embodiment

Next, a second embodiment will be described. Since the plasma processing apparatus 1 according to the second embodiment has the same configuration as the plasma processing apparatus 1 according to the first embodiment illustrated in FIG. 1, a description thereof will be omitted.

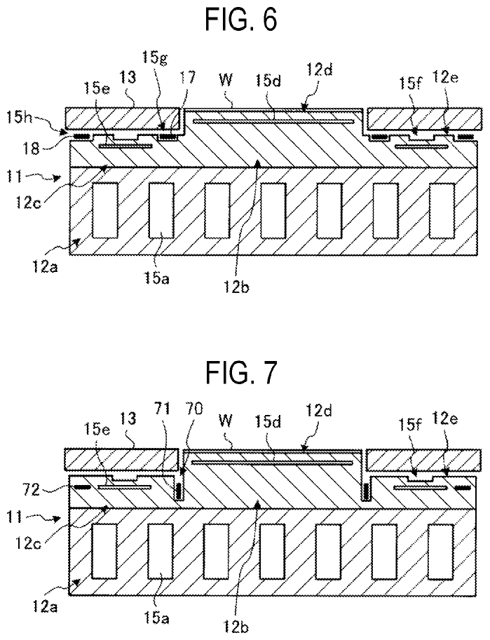

FIG. 6 is a schematic cross-sectional view illustrating the configuration of a main part of the stage 11 according to the second embodiment. The stage 11 according to the second embodiment has partially the same configuration as the stage 11 according to the first embodiment illustrated in FIG. 2. Thus, the same parts are designated by the same reference numerals, a description thereof will be omitted, and different parts will be mainly described.

The stage 11 according to the second embodiment is provided with heaters 17 and 18 on the top surface thereof on which the placement surface 12e is formed. For example, the second placement table 12c is provided with recesses 15g and 15h on the inner peripheral side and the outer peripheral side of the top surface thereof, respectively. The recesses 15g and 15h extend in an annular shape on the inner peripheral side and the outer peripheral side of the second placement table 12c in the circumferential direction of the edge ring 13. The heater 17 is provided in the recess 15g on the inner peripheral side. The heater 18 is provided in the recess 15h on the outer peripheral side.

In the stage 11 according to the second embodiment, heating is performed by providing the heaters 17 and 18 in the vicinity of the surface serving as an inner peripheral side entrance and an outer peripheral side entrance of the gap between the edge ring 13 and the placement surface 12e. As a result, the stage 11 is able to raise the temperature in the vicinity of the inner peripheral side entrance and the outer peripheral side entrance of the gap so that the deposition of a by-product in the gap can be suppressed.

As described above, in the stage 11 according to the second embodiment, the heaters 17 and 18 are provided above the arrangement surface on which the second electrostatic clamping electrode 15e is arranged. Therefore, with the stage 11, it is possible to efficiently heat the vicinity of the inner peripheral side entrance and the outer peripheral side entrance of the gap between the edge ring 13 and the placement surface 12e so that the deposition of a by-product in the gap can be suppressed.

Further, the heaters 17 and 18 are provided on the placement surface 12e on which the edge ring 13 is placed. Therefore, with the stage 11, it is possible to efficiently heat the vicinity of the surface forming the inner peripheral side entrance and the outer peripheral side entrance of the gap between the edge ring 13 and the placement surface 12e so that the deposition of a by-product in the gap can be suppressed.

### Third Embodiment

Next, a third embodiment will be described. Since the plasma processing apparatus 1 according to the third embodiment has the same configuration as the plasma processing apparatus 1 according to the first embodiment illustrated in FIG. 1, a description thereof will be omitted.

FIG. 7 is a schematic cross-sectional view illustrating the configuration of a main part of the stage 11 according to the third embodiment. The stage 11 according to the third embodiment has partially the same configuration as the stage 11 according to the first embodiment illustrated in FIG. 2. Thus, the same parts are designated by the same reference numerals, a description thereof will be omitted, and different parts will be mainly described.

In the stage 11 according to the third embodiment, a groove 70 is formed between the first placement table 12b and the second placement table 12c. The groove 70 extends in an annular shape between the first placement table 12b and the second placement table 12c. The groove 70 is formed to be deeper than the position of the second electrostatic clamping electrode 15e. The top surface of the stage 11 is divided into a first placement table 12b and a second placement table 12c by the groove 70.

The stage 11 according to the third embodiment is provided with the Peltier elements 71 and 72 in the second placement table 12c. The Peltier element 71 is provided on the inner peripheral side of the edge ring 13 with respect to the second electrostatic clamping electrode 15e. For example, the Peltier element 71 is provided along the groove 70. The Peltier element 72 is provided on the outer peripheral side of the edge ring 13 with respect to the second electrostatic clamping electrode 15e. For example, the Peltier element 72 is provided on the outer peripheral side of the second electrostatic clamping electrode 15e in the same surface as the arrangement surface in which the second electrostatic clamping electrode 15e is arranged such that a region in which the Peltier element 72 is arranged does not overlap the region of the second electrostatic clamping electrode 15e.

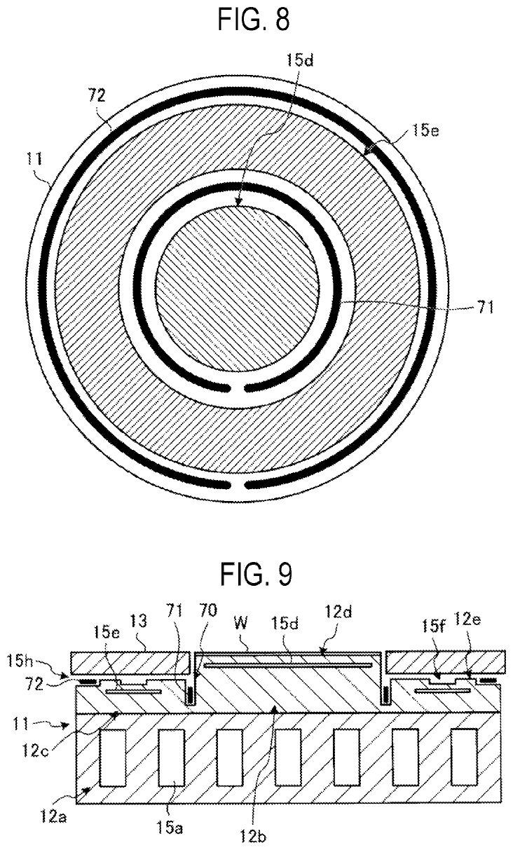

FIG. 8 is a view illustrating an example of arrangement regions of the first electrostatic clamping electrode 15d, the second electrostatic clamping electrode 15e, and the Peltier elements 71 and 72 according to the third embodiment. FIG. 8 illustrates a conceptual view of the stage 11 viewed from above (at the placement surface 12d, 12e side). The Peltier elements 71 and 72 are provided along the entire circumference of the second placement table 12c on the inner peripheral side and the outer peripheral side, respectively.

Power is supplied to the Peltier elements 71 and 72 from a power supply different from the DC power supply 21 under the control of the controller 100. The Peltier elements 71 and 72 are capable of transferring heat when a direct current flows therethrough from the power supply. The Peltier elements 71 and 72 are capable of changing the direction of heat transfer by changing the direction of the direct current flowing from the power supply, and are thus able to perform cooling or heating.

During plasma processing, the plasma processing apparatus 1 according to the third embodiment supplies a direct current from a power supply such that the Peltier elements 71 and 72 perform cooling under the control of the controller 100. In the stage 11, the groove 70 is cooled by the Peltier element 71, and the outer surface of the second placement table 12c is cooled by the Peltier element 72. A by-product produced by plasma processing adheres to a cold portion. In the stage 11 according to the third embodiment, by lowering the temperature of the Peltier elements 71 and 72, the by-product produced by the plasma processing adheres and accumulates to the groove 70 and the outer surface of the second placement table 12c. That is, in the stage 11 according to the third embodiment, the by-product produced during the plasma processing is trapped in the groove 70 and on the outer surface of the second placement table 12c. Therefore, with the stage 11 according to the third embodiment, it is possible to suppress deposition of a deposit in the gap between the edge ring 13 and the placement surface 12e.

When performing plasma cleaning, the plasma processing apparatus 1 according to the third embodiment may supply a direct current from a power supply such that the Peltier elements 71 and 72 perform heating under the control of the controller 100. For example, when a higher temperature causes an increase in the rate of removal of a by-product, the plasma processing apparatus 1 supplies a direct current from the power supply such that the Peltier elements 71 and 72 perform heating under the control of the controller 100. Therefore, with the plasma processing apparatus 1 according to the third embodiment, it is possible to quickly remove the deposited by-product.

The case in which, in the stage 11 according to the third embodiment, the Peltier elements 71 and 72 are provided on both the inner peripheral side and the outer peripheral side of the edge ring 13 with respect to the second electrostatic clamping electrode 15e has been described as an example, but the stage 11 is not limited thereto. The stage 11 may be provided with only one of the Peltier elements 71 and 72. That is, the stage 11 may have a Peltier element on at least one of the inner peripheral side and the outer peripheral side of the edge ring 13 with respect to the second electrostatic clamping electrode 15e.

As described above, the second placement table 12c of the stage 11 according to the third embodiment includes the second electrostatic clamping electrode 15e and the Peltier elements 71 and 72 (a temperature adjuster). The second electrostatic clamping electrode 15e clamps the edge ring 13 by being applied with the voltage. The Peltier elements 71 and 72 are provided on at least one of the inner peripheral side and the outer peripheral side of the edge ring 13 with respect to the second electrostatic clamping electrode 15e. Therefore, with the stage 11, it is possible to suppress the deposition of a deposit in the gap between the edge ring 13 and the placement surface 12e, on which the edge ring 13 is placed.

In addition, the Peltier element 71 is provided in the groove 70 formed in an annular shape between the first placement table 12b and the second placement table 12c. Therefore, with the stage 11, it is possible to suppress the deposition of a deposit in the gap between the edge ring 13 and the placement surface 12e, on which the edge ring 13 is placed since the by-product produced by the plasma processing can be trapped in the groove 70.

The plasma processing apparatus 1 according to the third embodiment includes a power supply configured to supply electric power to the Peltier elements 71 and 72 and a controller 100 configured to control the power supply such that the Peltier elements 71 and 72 perform cooling during plasma processing and perform heating during plasma cleaning. Therefore, with the plasma processing apparatus 1, it is possible to suppress the deposition of the deposit in the gap between the edge ring 13 and the placement surface 12e on which the edge ring 13 is placed during the plasma processing, and to quickly remove the deposited by-product during the plasma cleaning.

### Fourth Embodiment

Next, a fourth embodiment will be described. Since the plasma processing apparatus 1 according to the fourth embodiment has the same configuration as the plasma processing apparatus 1 according to the first embodiment illustrated in FIG. 1, a description thereof will be omitted.

FIG. 9 is a schematic cross-sectional view illustrating the configuration of a main part of the stage 11 according to the fourth embodiment. The stage 11 according to the fourth embodiment has partially the same configuration as the stages 11 according to the second and third embodiments illustrated in FIGS. 6 and 8. Thus, the same parts are designated by the same reference numerals, a description thereof will be omitted, and different parts will be mainly described.

In the stage 11 according to the fourth embodiment, a groove 70 is formed between the first placement table 12b and the second placement table 12c. The groove 70 extends in an annular shape between the first placement table 12b and the second placement table 12c. The top surface of the stage 11 is divided into a first placement table 12b and a second placement table 12c by the groove 70. In addition, the second placement table 12c is provided with a recess 15h on the outer peripheral side of the top surface thereof. The recess 15h extends in an annular shape on the outer peripheral side of the second placement table 12c in the circumferential direction of the edge ring 13.

The stage 11 according to the fourth embodiment is provided with Peltier elements 71 and 72 in the second placement table 12c. The Peltier element 71 is provided on the inner peripheral side of the edge ring 13 with respect to the second electrostatic clamping electrode 15e. For example, the Peltier element 71 is provided along the groove 70. The Peltier element 72 is provided on the outer peripheral side of the edge ring 13 with respect to the second electrostatic clamping electrode 15e. For example, the Peltier element 72 is provided in the recess 15h.

During plasma processing, the plasma processing apparatus 1 according to the fourth embodiment supplies a direct current from a power supply such that the Peltier elements 71 and 72 perform cooling under the control of the controller 100. Therefore, the by-product produced by the plasma processing adheres and accumulates to the lower portion of the groove 70 and the recess 15h. That is, in the stage 11 according to the third embodiment, the by-product produced during the plasma processing is trapped in the groove 70 and the recess 15h. Therefore, with the stage 11 according to the fourth embodiment, it is possible to suppress the deposition of a deposit in the gap between the edge ring 13 and the placement surface 12e.

When performing plasma cleaning, the plasma processing apparatus 1 according to the fourth embodiment may supply a direct current from a power supply such that the Peltier elements 71 and 72 perform heating under the control of the controller 100, as in the third embodiment.

As described above, in the stage 11 according to the fourth embodiment, the Peltier elements 71 and 72 are provided in the groove 70 formed in an annular shape between the first placement table 12b and the second placement table 12c and the recess 15h formed along the outer periphery of the second placement table 12c, respectively. Therefore, with the stage 11, it is possible to suppress the deposition of a deposit in the gap between the edge ring 13 and the placement surface 12e, on which the edge ring 13 is placed.

Although embodiments have been described above, it should be considered that the embodiments disclosed herein are illustrative and are not restrictive in all respects. Indeed, the embodiments described above can be implemented in various forms. In addition, the embodiments described above may be omitted, replaced, or modified in various forms without departing from the scope and spirit of the claims.

For example, in the above-described embodiments, the case in which the plasma processing apparatus 1 is a capacitive coupling type plasma processing apparatus has been described as an example, but the plasma processing apparatus 1 is not limited thereto. The plasma-processing apparatus 1 may be any type of plasma-processing apparatus, such as an inductively coupled plasma processing apparatus or a plasma processing apparatus that excites gas by surface waves such as microwaves.

It should be understood that the above-described embodiments disclosed herein are exemplary in all respects and are not restrictive. The above-described embodiments may be omitted, replaced, or modified in various forms without departing from the scope and spirit of the appended claims.

According to the present disclosure, it is possible to suppress the deposition of a by-product in a gap between an edge ring and a placement surface on which the edge ring is placed.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A stage comprising:
a first placement table on which a substrate is placed; and
a second placement table configured to place thereon a ring-shaped edge ring arranged around the substrate,
wherein the second placement table includes:
an electrostatic clamping electrode configured to clamp the edge ring by being applied with a voltage; and
a temperature adjuster provided on at least one of an inner peripheral side and an outer peripheral side of the edge ring with respect to the electrostatic clamping electrode.

2. The stage of claim 1, wherein the temperature adjuster is provided in the second placement table such that a region in which the temperature adjuster is arranged does not overlap with a region of the electrostatic clamping electrode when viewed at a placement surface side on which the edge ring is placed.

3. The stage of claim 2, wherein the temperature adjuster is provided on a same surface as an arrangement surface on which the electrostatic clamping electrode is arranged, or above the arrangement surface.

4. The stage of claim 3, wherein the temperature adjuster is provided along an entire circumference of the second placement table.

5. The stage of claim 4, wherein the temperature adjuster is a heater.

6. The stage of claim 5, wherein the heater is provided on a placement surface on which the edge ring is placed.

7. The stage of claim 6, wherein the heater is provided on a same surface as that of the electrostatic clamping electrode, and one end of the heater is connected to one end of the electrostatic clamping electrode.

8. The stage of claim 1, wherein the temperature adjuster is provided on a same surface as an arrangement surface on which the electrostatic clamping electrode is arranged, or above the arrangement surface.

9. The stage of claim 1, wherein the temperature adjuster is provided along an entire circumference of the second placement table.

10. The stage of claim 1, wherein the temperature adjuster is a heater.

11. The stage of claim 5, wherein the heater is provided on a same surface as that of the electrostatic clamping electrode, and one end of the heater is connected to one end of the electrostatic clamping electrode.

12. The stage of claim 1, wherein the temperature adjuster is a Peltier element.

13. The stage of claim 12, wherein the Peltier element is provided in at least one of a groove formed in an annular shape between the first placement table and the second placement table and a recess formed along an outer periphery of the second placement table.

14. A plasma processing apparatus comprising the stage of claim 1.

15. A plasma processing apparatus comprising:
the stage of claim 13;
a power supply configured to supply power to the Peltier element; and
a controller configured to control the power supply such that the Peltier element performs cooling during plasma processing and performs heating during plasma cleaning.
